(19) United States
(12) Patent Application Publication
(10) Pub. No.: US 2007/0036191 A1
(43) Pub. Date: Feb. 15, 2007

(54) MICRO-LENS BUILT-IN LASER CAPABLE OF ADJUSTING A LIGHT RADIATION ANGLE AND METHOD OF MANUFACTURING THE SAME

(76) Inventor: Jeng-Feng Lan, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/161,679

(22) Filed: Aug. 11, 2005

(51) Int. Cl. H01S 5/00; H01S 3/08

(52) U.S. Cl. 372/50.23; 372/101; 372/103

(57) ABSTRACT

A micro-lens built-in laser includes a light source, a transparent layer and a micro-lens. The light source emits light. The micro-lens and the light source are formed on a same substrate in a same semiconductor process. The micro-lens refracts and adjusts light beams emitted from the light source, and the adjusted light is emitted at an emitting surface of the micro-lens. The micro-lens built-in laser controls its radiation angle by changing the thickness of the transparent layer and the shape of the micro-lens.

### BACKGROUND OF THE INVENTION

1. Field of the Invention

The present invention is related to a laser capable of adjusting a light radiation angle and a method of manufacturing the same, and more particularly, to a micro-lens built-in laser capable of adjusting a light radiation angle and a method of manufacturing the same.

2. Description of the Prior Art

With the widespread use of the internet, rapidly increased demands on internet capacity accelerate the development of optical fiber communication. Light sources are active devices in optical fiber communication systems, with which electrical signals can be transformed into optical signals and then coupled to optical fibers effectively. There are various types of light sources. Due to the coherent nature, high power and low energy consumption of laser illumination, laser is a favored choice for light sources used in optical fiber communication systems. Besides optical fiber communication systems, laser light sources can also be applied to digital communication systems, household digital electronic devices and household internet networks, etc.

For example, there are three types of laser light sources commonly adopted in optical fiber communication systems: Fabry-Perot (FP) laser, distributed feedback (DFB) laser, and vertical cavity surface emitting laser (VCSEL). VCSELs provide low threshold current, single-mode operation, low beam diversion, effective coupling to single-mode optical fibers, long lifetime, and simple manufacturing processes. Therefore, VCSELs are wisely used in optical fiber communication systems.

A VCSEL emits light from a resonant cavity formed between epitaxial layers. The light is emitted in a perpendicular direction with respect to the epitaxial layers instead of the conventional lateral light emission. To couple the light to the optical fiber effectively, a transverse confinement is required for restraining the area from which laser beams are emitted. Based on the method of transverse confinement, VCSELs can further be categorized into two types: implanted VCSEL and oxide isolation VCSEL.

Please refer to FIG. 1 for a diagram illustrating a prior art VCSEL 10. The VCSEL 10, using ion implantation for transverse confinement, includes a substrate 12, a lower epitaxial layer 14, an active layer 15, an upper epitaxial layer 16, an ion-implanted layer 17, a metal layer 18, and a protecting layer 19. The lower epitaxial layer 14 and the upper epitaxial layer 16, each of which comprises a plurality of layers of different materials, include materials of opposite doping types. For example, if the substrate 12 is an N-type substrate, then the upper epitaxial layer 16 can include P-type semiconductor material and the lower epitaxial layer 14 can include N-type semiconductor material. Electrons and holes, provided by the lower epitaxial layer 14 and the upper epitaxial layer 16 respectively, are combined in the active layer 15 for generating light, which in turn is emitted through an opening of the metal layer 18. The protecting layer 19 can include transparent material for protecting the opening of the metal layer 18 without affecting light emission. The ion-implanted layer 17 of the VCSEL 10 is formed in an ion implantation process for defining radiating and non-radiating regions of the VSCEL 10, so that the current generated by the lower epitaxial layer 14 and the upper epitaxial layer 16 flows through the radiating region in a funneled form, as shown in FIG. 1. Since ion implantation is a planer process and does not require etching steps, the VCSEL 10 can be fabricated in an uncomplicated process. Though the simple process is preferable in mass production, it provides limited transverse confinement for the VCSEL 10.

Please refer to FIG. 2 for a diagram illustrating another prior art VCSEL 20. The VCSEL 20, using oxidation isolation for transverse confinement, includes the substrate 12, the lower epitaxial layer 14, the active layer 15, the upper epitaxial layer 16, an oxide layer 27, and the metal layer 18. Similar to the VCSEL 10, electrons and holes, provided by the lower epitaxial layer 14 and the upper epitaxial layer 16 respectively, are combined in the active layer 15 for generating light, which in turn is emitted through the opening of the metal layer 18. The VCSEL 20 differs from the VCSEL 10 in that the VCSEL 20 adopts oxidation isolation for transverse confinement. The oxide layer 27 is formed by injecting gas in a high-temperature process for oxidizing materials. Radiant and non-radiant regions can be defined in an etching process for controlling the radiation angle of the VCSEL 20.

Many applications require collimated light or light with small radiation angle. No matter if ion implantation or oxide isolation is used for transverse confinement, light provided by the VCSEL 10 and the VCSEL 20 still has a certain radiation angle. Take an optical fiber communication system for example. In order to couple the light to the optical fiber effectively, an extra set of lenses is disposed at the VCSEL 10, the VCSEL 20 and an input end of the optical fiber in the prior art. Also, the focuses of the light emitted by the VCSEL 10 and the VCSEL 20 and the focus of the condensed light by the extra set of lenses have to be adjusted for better optical efficiency. Therefore, the prior art laser light sources require extra devices and adjustment procedures and thus complicate designs for the optical fiber communication system.

### SUMMARY OF THE INVENTION

It is therefore a primary objective of the claimed invention to provide a light source in order to solve the problems of the prior art.

According to a first exemplary embodiment of the claimed invention, a micro-lens built-in laser capable of adjusting a light radiation angle comprises a light source for emitting light, and a micro-lens formed on a same chip with the light source in a semiconductor process for refracting and adjusting light emitted by the light source and emitting the adjusted light at an emitting surface of the micro-lens.

According to a second exemplary embodiment of the claimed invention, an apparatus capable of providing laser light comprises a laser light source for emitting light, and a micro-lens formed on a same chip with the laser light source in a semiconductor process for refracting and adjusting light emitted by the laser light source and emitting the adjusted light at an emitting surface of the micro-lens.

According to a third exemplary embodiment of the claimed invention, a method of manufacturing a laser light source comprises forming a laser light source on a chip for emitting light, and forming a micro-lens on the chip for refracting and adjusting light emitted by the laser light source.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a prior art vertical cavity surface emitting laser.

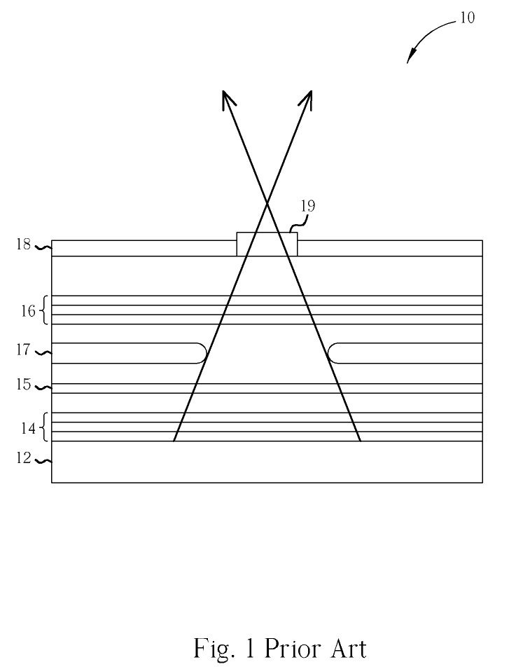

FIG. 2 shows another prior art vertical cavity surface emitting laser.

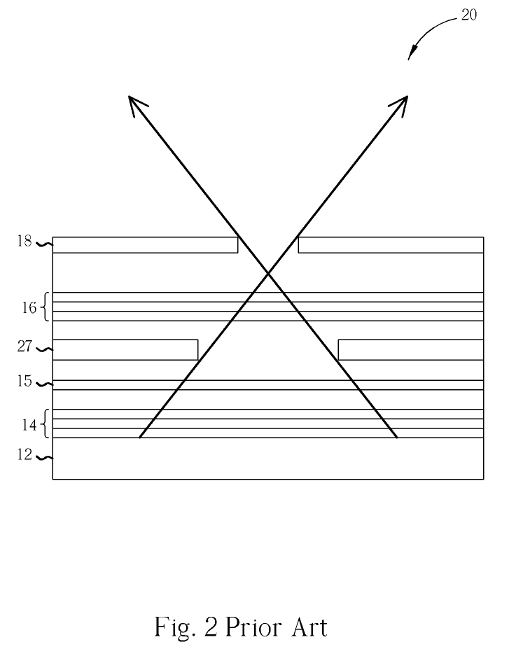

FIG. 3 shows a vertical cavity surface emitting laser according to a first embodiment of the present invention.

FIG. 4 shows a vertical cavity surface emitting laser according to a second embodiment of the present invention.

FIG. 5 shows a vertical cavity surface emitting laser according to a third embodiment of the present invention.

FIG. 6 shows a vertical cavity surface emitting laser according to a fourth embodiment of the present invention.

### DETAILED DESCRIPTION

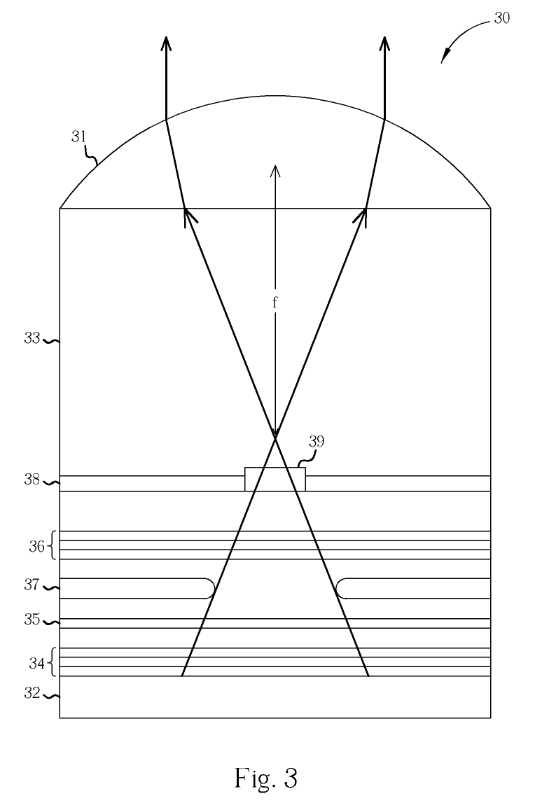

Please refer to FIG. 3 for a diagram illustrating a VCSEL 30 according to a first embodiment of the present invention. The VCSEL 30, using ion implantation for transverse confinement, includes a micro-lens 31, a substrate 32, a transparent layer 33, a lower epitaxial layer 34, an active layer 35, an upper epitaxial layer 36, an ion-implanted layer 37, a metal layer 38, and a protecting layer 39. The lower epitaxial layer 34 and the upper epitaxial layer 36, each of which comprises a plurality of layers of different materials, include materials of opposite doping types. For example, if the substrate 32 is an N-type substrate, then the upper epitaxial layer 36 can include P-type semiconductor material and the lower epitaxial layer 34 can include N-type semiconductor material. Electrons and holes, provided by the lower epitaxial layer 34 and the upper epitaxial layer 36 respectively, are combined in the active layer 35 for generating light, which in turn is emitted through an opening of the metal layer 38. The protecting layer 39 can include transparent material for protecting the opening of the metal layer 38 without affecting light emission. The ion-implanted layer 37 of the VCSEL 30 is formed in an ion implantation process for defining radiating and non-radiating regions of the VCSEL 30, so that the current generated by the lower epitaxial layer 34 and the upper epitaxial layer 36 flows through the radiating region in a funneled form, as shown in FIG. 3.

The micro-lens 31 and the transparent layer 33 of the VCSEL 30 are formed on the metal layer 38. The micro-lens 31 refracts light emitted through the opening of the metal layer 38 for adjusting the radiation angle of the VCSEL 30. In the first embodiment of the present invention, the micro-lens 31 is a convex lens capable of condensing light such that the VCSEL 30 can provide collimated light. The transparent layer 33 can be formed using light-transparent materials, such as silicon nitride. By changing the thickness of the transparent later 33, the distance between the micro-lens 31 and the metal layer 38 can be adjusted. In the first embodiment of the present invention, the micro-lens 31 is formed at a certain distance from the metal layer 38 so that the micro-lens 31 is located at a focus “f” of the light emitted through the opening of the metal layer 38.

All devices of the VCSEL 30 are formed in a same semiconductor process. The micro-lens 31 can adjust the radiation angle of the VCSEL 30 and thus it is not necessary to include an extra set of lenses as required in the prior art VCSELs 10 and 20. By changing the thickness of the transparent later 33, the distance between the micro-lens 31 and the metal layer 38 can be adjusted. Therefore, the VCSEL 30 does not require extra adjustment procedures for better optical efficiency. Compared to the prior art the VCSELs 10 and 20, the VCSEL 30 of the present invention can provide collimated light using the built-in micro-lens 31 without extra lenses or adjustment procedures.

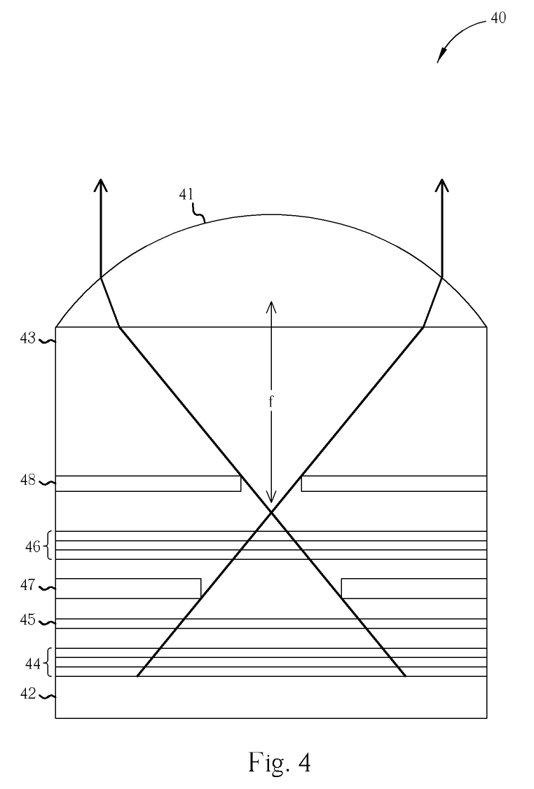

Please refer to FIG. 4 for a diagram illustrating a VCSEL 40 according to a second embodiment of the present invention. The VCSEL 40, using oxidation isolation for transverse confinement, includes a micro-lens 41, a substrate 42, a transparent layer 43, a lower epitaxial layer 44, an active layer 45, an upper epitaxial layer 46, an oxide layer 47, and a metal layer 48. Similar to the VCSEL 30, electrons and holes, provided by the lower epitaxial layer 44 and the upper epitaxial layer 46 respectively, are combined in the active layer 45 for generating light, which in turn is emitted through the opening of the metal layer 48. The VCSEL 40 differs from the VCSEL 30 in that the VCSEL 40 adopts oxidation isolation for transverse confinement. The oxide layer 47 is formed by injecting gas in a high-temperature process for oxidizing materials. Radiant and non-radiant regions can be defined in an etching process for controlling the radiation angle of the VCSEL 40.

The micro-lens 41 and the transparent layer 43 of the VCSEL 40 are formed on the metal layer 48. The micro-lens 41 refracts light emitted through the opening of the metal layer 48 for adjusting the radiation angle of the VCSEL 40. In the second embodiment of the present invention, the micro-lens 41 is a convex lens capable of condensing lens such that the VCSEL 40 can provide collimated light. The transparent layer 43 can be formed using light-transparent materials, such as silicon nitride. By changing the thickness of the transparent layer 43, the distance between the micro-lens 41 and the metal layer 48 can be adjusted. In the second embodiment of the present invention, the micro-lens 41 is formed at a certain distance from the metal layer 48 so that the micro-lens 41 is located at a focus “f” of the light emitted through the opening of the metal layer 48.

All devices of the VCSEL 40 are formed in a same semiconductor process. The micro-lens 41 can adjust the radiation angle of the VCSEL 40 and thus it is not necessary to include an extra set of lenses as required in the prior art VCSELs 10 and 20. By changing the thickness of the transparent later 43, the distance between the micro-lens 41 and the metal layer 48 can be adjusted. Therefore, the VCSEL 40 does not require extra adjustment procedures for better optical efficiency. Compared to the prior art the VCSELs 10 and 20, the VCSEL 40 of the present invention can provide collimated light using the built-in micro-lens 41 without extra lenses or adjustment procedures.

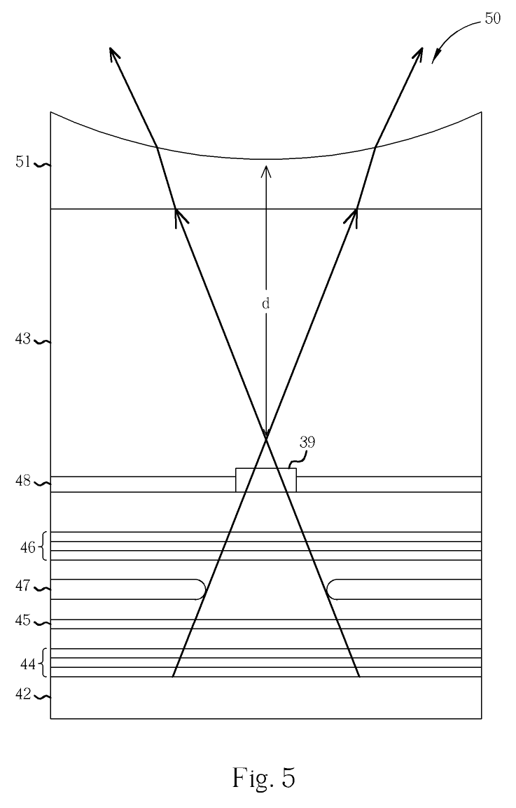

Please refer to FIG. 5 for a diagram illustrating a VCSEL 50 according to a third embodiment of the present invention. The VCSEL 50 uses ion implantation for transverse confinement and differs from the VCSEL 30 in that a micro-lens 51 of the VCSEL 50 is a concave lens. All devices of the VCSEL 50 are also formed in a same semiconductor process. The micro-lens 51 can adjust the radiation angle of the VCSEL 50 without disposing an extra lens. By changing the distance “d” between the micro-lens 51 and the metal layer 48, the radiation angle of the VCSEL 50 can also be adjusted. Therefore, the VCSEL 50 does not require extra adjustment procedures for better optical efficiency. Compared to the prior art the VCSELs 10 and 20, the VCSEL 50 of the present invention can adjust the radiation angle using the built-in micro-lens 51 without extra lenses or adjustment procedures.

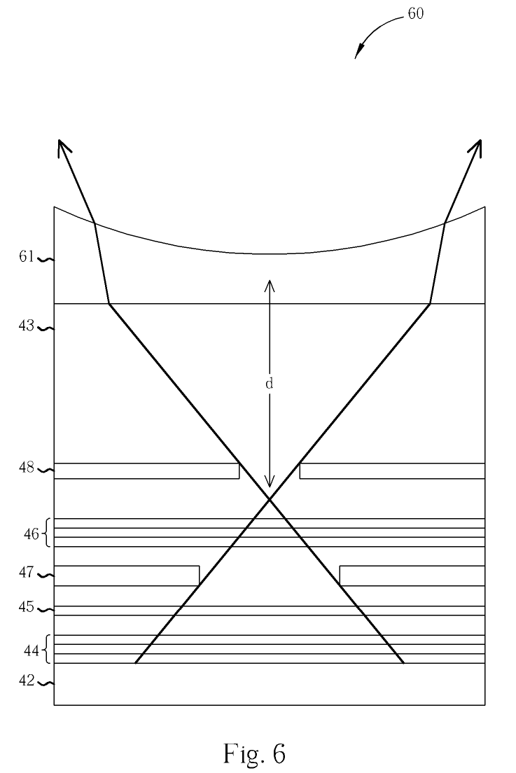

Please refer to FIG. 6 for a diagram illustrating a VCSEL 60 according to a fourth embodiment of the present invention. The VCSEL 60 uses ion implantation for transverse confinement and differs from the VCSEL 40 in that a micro-lens 61 of the VCSEL 60 is a concave lens. All devices of the VCSEL 60 are also formed in a same semiconductor process. The micro-lens 61 can adjust the radiation angle of the VCSEL 60 without disposing an extra lens. By changing the distance “d” between the micro-lens 61 and the metal layer 48, the radiation angle of the VCSEL 60 can be adjusted. Therefore, the VCSEL 60 does not require extra adjustment procedures for better optical efficiency. Compared to the prior art the VCSELs 10 and 20, the VCSEL 60 of the present invention can adjust the radiation angle using the built-in micro-lens 61 without extra lenses or adjustment procedures.

In the present invention, all devices of the VCSELs 30-60 are formed in a same semiconductor process and the radiation angles of the VCSELs 30-60 can be adjusted by changing the thickness of respective transparent layers and the shape of respective micro-lenses. The micro-lens of the present invention can be the convex lenses or the concave lenses shown in FIG. 3-6, or other types of lenses designed for different radiation angles. Also, the micro-lens can be formed at a focus “f” of the light emitted through the opening of the metal layer, or at other distances for different applications.

In applications that require collimated light or light with small radiation angle, the prior art laser light sources require extra devices and adjustment procedures and thus increase the complexity of the optical fiber communication system. Compared to the prior art, the present invention adjusts the radiation angle of the laser light source using the built-in micro-lens. All devices of the present laser light sources are formed in the same semiconductor process. By changing the thickness of the transparent layer and the shape of the micro-lens, the present invention can provide collimated light and light with various radiation angles. The present invention can simplify designs for optical systems and improve optical efficiency. The laser light sources according to the present invention can be applied to optical communication systems, digital communication systems, household digital electronic devices, household Internet networks, and personal computer input devices, etc.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-lens built-in laser capable of adjusting a light radiation angle comprising:
a light source for emitting light; and
a micro-lens formed on a same chip with the light source in a semiconductor process for refracting and adjusting light emitted by the light source and emitting the adjusted light at an emitting surface of the micro-lens.

2. The laser of claim 1 wherein the micro-lens refracts and adjusts the light emitted by the light source for generating collimated light and emitting the adjusted collimated light at the emitting surface of the micro-lens.

3. The laser of claim 1 further comprising a transparent layer formed between the light source and the micro-lens.

4. The laser of claim 3 wherein the transparent layer includes silicon nitride.

5. The laser of claim 1 wherein the micro-lens is a convex lens.

6. The laser of claim 1 wherein the micro-lens is a concave lens.

7. The laser of claim 1 wherein the micro-lens is formed at a focus of the light emitted by the light source.

8. The laser of claim 1 being a vertical cavity surface emitting laser.

9. An apparatus capable of providing laser light comprising:
a laser light source for emitting light; and
a micro-lens formed on a same chip with the laser light source in a semiconductor process for refracting and adjusting light emitted by the laser light source and emitting the adjusted light at an emitting surface of the micro-lens.

10. The apparatus of claim 9 further comprising a transparent layer formed between the laser light source and the micro-lens.

11. The apparatus of claim 10 wherein the transparent layer includes silicon nitride.

12. The apparatus of claim 9 wherein the micro-lens is a convex lens.

13. The apparatus of claim 9 wherein the micro-lens is a concave lens.

14. The apparatus of claim 9 wherein the micro-lens is formed at a focus of the light emitted by the laser light source.

15. The apparatus of claim 1 wherein the laser light source is a vertical cavity surface emitting laser.

16. A method of manufacturing a laser light source comprising:
forming a laser light source on a chip for emitting light; and
forming a micro-lens on the chip for refracting and adjusting light emitted by the laser light source.

17. The method of claim 16 further comprising forming a transparent layer between the laser light source and the micro-lens.

18. The method of claim 16 wherein the micro-lens is formed in a semiconductor process.
